(19) United States
(12) Patent Application Publication
(10) Pub. No.: US 2008/0303512 A1
(43) Pub. Date: Dec. 11, 2008

(54) Isolating Transformer

(75) Inventors: Claude Gudel, Archamps (FR); Francois Marquet, Crozet (FR)

Correspondence Address: BAKER & DANIELS LLP, 300 NORTH MERIDIAN STREET, SUITE 2700, INDIANAPOLIS, IN, 46204, US

(73) Assignee: Liaisons Electroniques-Mecaniques Lem Sa, Plan-Les-Ouates (CH)

(21) Appl. No.: 11/791,239

(22) PCT Filed: Oct. 21, 2005
(86) PCT No.: PCT/IB2005/003199

§ 371 Date: May 21, 2007

(30) Foreign Application Priority Data
Nov. 23, 2004 (EP) 04405726.3

(51) Int. Cl. G01R 15/18; H01F 27/28

(52) U.S. Cl. 324/127; 336/180

(57) ABSTRACT

Electrical power supply for electronic circuits arranged in a high voltage environment, which supply includes an isolating device interconnecting the low voltage side (secondary side) and the high voltage side (primary side) and including a primary side magnetic circuit (13a) coupled via a primary coil (14) to a power supply (12) of the electronic circuit in the high voltage environment, a secondary side magnetic circuit (13c) coupled via a secondary coil (15) to a low voltage side voltage source (10), and at least one intermediate magnetic circuit (13b) located between the primary and secondary magnetic circuits and coupled thereto via intermediate coils (16, 17) that include coil turn portions in the form of U-shaped conductors mounted to at least one circuit board (18, 19) that includes conducting tracks interconnecting the U-shaped conductors to close the turn portions of the intermediate coils.

This present invention concerns an electrical power supply for circuits or electronic devices placed in a high-voltage environment and necessitating electrical insulation, for safety and other reasons. The invention in particular concerns a power supply for a measuring device, in particular an electrical sensor, placed in a high-voltage environment.

For many high-voltage electrical systems, it is desired to measure the current or the voltage for purposes of monitoring and adjustment. One of the many applications is the measurement of electrical magnitudes on the high-voltage lines of railway systems, which require insulation voltages of up to 12 kV.

In order to avoid problems of electrical insulation between the high-voltage and low-voltage sides, it is known for certain current and voltage sensors to draw the electrical energy that they need for their operation from the high-voltage lines to which they are coupled for measurement of the electrical magnitudes. This is generally possible if the electrical energy used for the operation of the measuring device is small in relation to the electrical energy flowing in the high-voltage lines to be measured. Such a power supply is nevertheless difficult to arrange, and has certain disadvantages. Firstly, the transformer necessary to draw down electrical energy from a high-voltage line in order to power the electronic device can be created only if the frequency of the high-voltage current is known and stable. Secondly, it is advantageous to be able to use the measuring device in different alternating current or direct current systems, without significant modifications, and in particular without having to modify the power-supply arrangements.

One specific problem, in the case of measuring differential voltages between two phases, is that it is not possible to precisely measure the “zero” point, that is when the potential difference between the two phases is zero, since the sensor is not powered when the differential voltage is zero.

Another solution would consist of supplying the electrical energy for the operation of the electronic device by drawing this energy from the low-voltage side. Such a power supply would allow one to eliminate or alleviate the aforementioned drawbacks, but would then require a solution to the problem of electrical insulation.

In power supply systems placed between a low-voltage side (secondary) and a high-voltage side (primary), it is known that one can insert an isolating device between the primary and secondary sides, in the form of a transformer with several magnetic circuits, as described in publications GB-A-2307795 and U.S. Pat. No. 4,172,244.

In GB-A-2307795, there is a description of an isolating transformer with two or three magnetic circuits, coupled together by intermediate windings, from the primary side to a primary winding, and from the secondary side to a secondary winding. In U.S. Pat. No. 4,172,244, there is also a proposal for having an intermediate magnetic circuit between the magnetic circuits of the primary and secondary sides, with the aim of creating electrical insulation and reducing the leakage currents resulting from capacitive coupling effects.

The measures proposed for the reduction of capacitive coupling include the insertion of electrical screening around the windings and reduction of the number of turns in the intermediate windings coupling the magnetic circuits together.

In spite of the measures proposed, in the conventional isolating transformers, the capacitive coupling between the primary and secondary sides and the generated parasitic electromagnetic waves still remain too high, in particular in applications in which the changes of potential (dv/dt) can be very high, which, for example, can be the case of the dv/dt in common mode on railway lines, which can reach up to 6 kV/μs. Secondly, the resistance to electrical surface leakages (creep resistance) can be insufficient, and in particular if the dielectric sheets separating the windings and the magnetic circuits deteriorate with time. A conventional construction of dielectric winding layers, with screening and casing of the isolating device, is also relatively expensive to construct and can suffer from heating problems during use.

In view of the above, one aim of the invention is to supply a power supply system for an electronic circuit placed in a high-voltage environment, having very good electrical insulation, a low level of partial discharges, a weak emission of parasitic electromagnetic waves and low level of capacitive coupling, even for a high dv/dt in common mode on the high-voltage side.

It is advantageous to supply a power supply system for an electronic device placed in a high-voltage environment, that is compact, reliable and low cost.

It is advantageous to supply an insulating device for a power supply system for an electronic circuit placed in a high-voltage environment, that has a very high resistance to electrical surface leakages and a very high breakdown voltage. Another aim of the invention is to supply a measuring device for the electrical magnitudes of high-voltage lines which is accurate and reliable, and which can tolerate high variations of dv/dt in common mode.

It is advantageous to supply a measuring device that can be used for measuring electrical magnitudes on high-voltage lines, but which can also be deployed easily and without significant modification in different environments and for different applications.

It is advantageous to supply a measuring device for electrical magnitudes on high-voltage lines, that has a very good electrical insulation, a low emission of parasitic electromagnetic waves, a weak capacitive coupling to the low-voltage side, a high resistance to electrical surface leakages and a very high breakdown voltage.

The aims of the invention are achieved by a system according to claim 1.

In this present invention, an electrical power supply for circuits placed in a high-voltage environment includes an insulating device interconnecting the low-voltage side (secondary side) to the high-voltage side (primary side), with the isolating device including a primary side magnetic circuit coupled by means of a primary winding to a power supply of the electronic circuit in the high-voltage environment, a secondary-side magnetic circuit coupled by means of a secondary winding to a current source, and at least one intermediate magnetic circuit between the primary and secondary magnetic circuits, coupled to the latter by means of intermediate windings, with the intermediate windings including parts of turns mounted on at least one circuit board.

The parts of the turns are preferably in the form of U-shaped conductors, where the circuit boards preferably include conducting tracks to interconnect the U-shaped conductors in order to close the turns of the intermediate windings.

Preferably, at least two circuit boards are used, one on the primary side and one on the secondary side, separated by an air space or a space filled with an insulating material, such as an epoxy resin, in order to increase the resistance to breakdown and the resistance to electrical surface leakages.

The U-shaped conductors of the parts of turns in the intermediate windings of the isolating device can be formed by stamping and positioned so as to be separated from the magnetic circuit by a space corresponding to about a quarter of the diameter of the opening formed by the magnetic circuit, or more. This enables the capacitive coupling between the windings and the magnetic circuits to be greatly reduced.

The intermediate windings can advantageously form a closed loop essentially in the form of an “8”, in order to cancel the magnetic leakage fields generated in these windings.

Preferably, the source of electrical energy on the low-voltage side is a stabilised sinusoidal voltage source, in order to avoid the generation of high harmonic frequencies that can disrupt the measurement signals.

The high-voltage side power supply can include a rectifier and filter circuit to generate a direct current without any alternating component.

In this present document, there is also a description of an appliance for measuring electrical magnitudes on high-voltage lines that includes a power supply device as described previously, a sensor placed on the high-voltage side, and a processing unit placed on the low-voltage side.

The sensor can include a differential voltage sensor for measuring differential voltages between two high-voltage phases, as well as an analogue-digital converter for transmission of the measurement signals to the processing unit. The sensor can also include an oscillator connected to the analogue-digital converter and sending a synchronising signal to digital-analogue converter of the processing unit in parallel with the digital measurement signal.

The processing unit and the sensor can communicate by means of optical fibres.

Other aims and advantageous aspects of the invention will emerge from the dependent claims, from the description that follows, and from the appended drawings, in which:

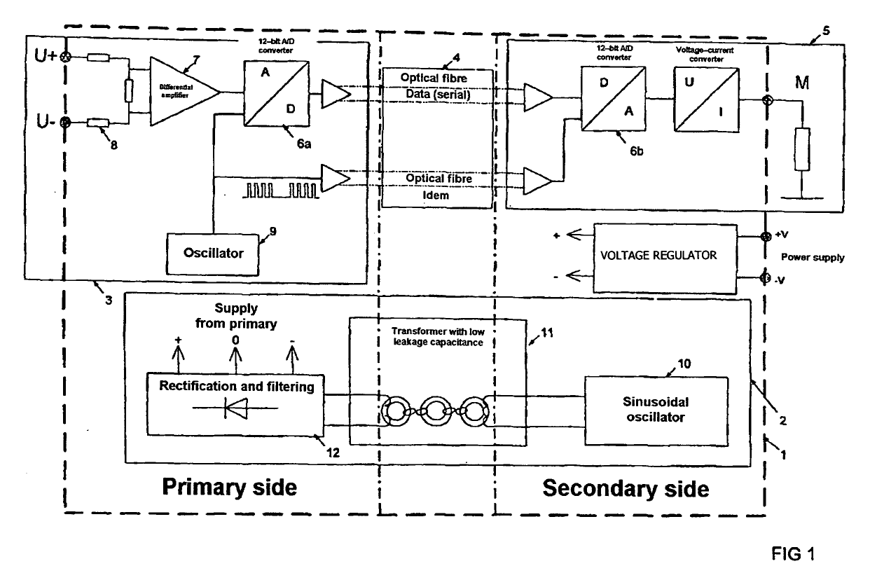

FIG. 1 is a diagram illustrating a measuring instrument, which in this case is an appliance for measuring differential voltages on high-voltage lines, including an electrical power supply according to the invention;

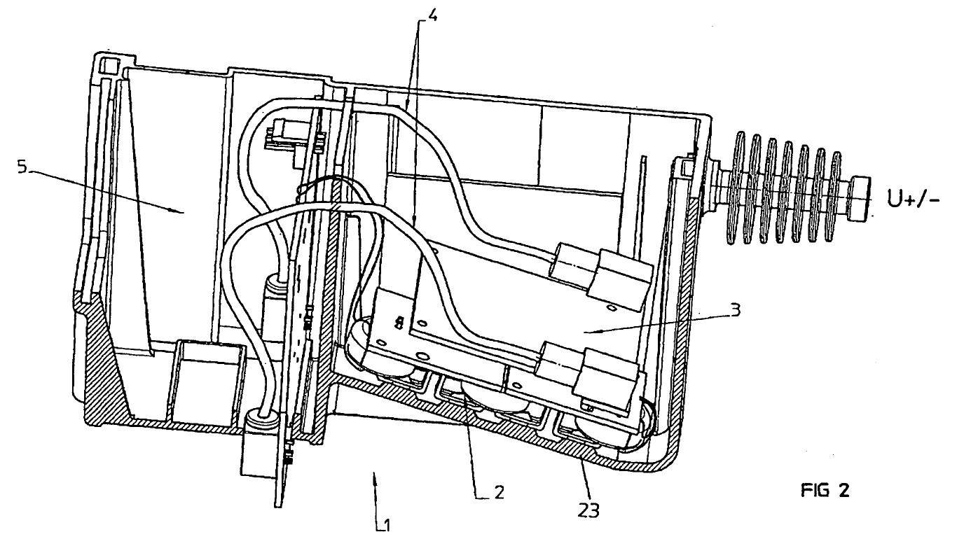

FIG. 2 is a view in section and in perspective of the differential-voltage measuring device for conducting lines in the railway domain;

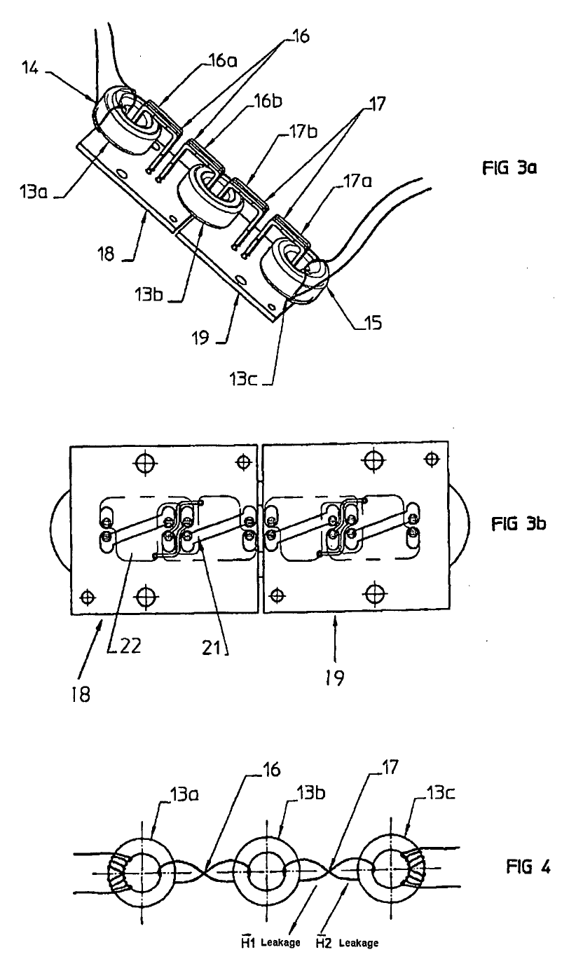

FIG. 3a is a view in perspective of an isolating device for the electrical power supply of the invention;

FIG. 3b is a plan view of the underside of the circuit boards of the isolating device according to the invention;

FIG. 4 is a schematic view in perspective, illustrating the coupling of the magnetic circuits of the isolating device by means of an intermediate winding.

Referring to the figures, in particular to FIGS. 1 and 2, a measuring device 1 for electrical magnitudes includes a power supply system 2, a signal processing unit 5, and a differential voltage sensor 3 placed in a high-voltage environment (primary side) and designed to measure electrical magnitudes on high-voltage lines. In the example shown, the voltage sensor measures the differential voltage between two phases of the high-voltage lines of a railway network having potentials of up to 6 kV.

The sensor transmits the measurement signals by a means other than electrical conductors, such as an optical fibre 4, or by electromagnetic waves, to the signal processing unit 5 placed on the low-voltage side (secondary side). The measuring device can include a case 23 in which the power supply and the signal processing circuits are mounted, and this case can be filled with a resin after assembly of the components (2, 3, 4, 5).

The electronic circuit 3 of the sensor can include an analogue-digital converter 6a in order to convert the analogue measurement signals, leaving the differential amplifier 7 connected through impedances 8 to the terminals of a sensor coupled to the two phases, into digital signals, for their transmission to the signal processing unit 5. For conversion of the digital signals into analogue signals by the digital-analogue converter 6b of the signal processing unit 5, an oscillator 9 of the sensor transmits a synchronising signal.

The power supply system 2 includes a voltage source 10 from the low-voltage side, preferably a stabilised sinusoidal voltage source, coupled through an insulating device 11 to a power supply unit 12 placed on the high-voltage side. The power supply unit is connected to the electronic circuit of the sensor 3 to provide it with electrical power. The power supply unit 12 includes a rectifier and filter circuit in order to convert sinusoidal input current into a direct current with no alternating component.

The sinusoidal current source 10 has the advantage, in comparison with switched current sources, of eliminating or reducing the high harmonic frequencies generated by the switched sources, in order not to disrupt the measurement signal produced by the sensor 3 and treated by the processing unit 5.

The isolating device according to the invention (see in particular FIGS. 1, 3a and 4) includes at least three magnetic circuits 13a, 13b, 13c, a primary-side circuit 13a, a secondary-side circuit 13c and an intermediate circuit 13b, where the circuits are preferably in the form of toroidal elements in a material with a good magnetic permeability. The isolating device also includes a primary winding 14 connected to the primary power supply unit 12, a secondary winding 15 connected to the voltage source 10 and intermediate windings 16, 17 mounted on circuit supports 18, 19 in the form of printed circuits.

The intermediate windings include intermediate turns 16a, 16b, 17a, 17b formed in part by preferably stamped, U-shaped metal elements mounted on the circuit boards 18, 19 and interconnected electrically by conducting tracks on the circuit boards, so as to form a closed loop essentially in the form of an “8”, as illustrated in FIG. 4. The tracks 21, 22 can be arranged in different layers of a multi-layer printed circuit, in order to enable them to be crossed so as to form the 8-shaped loop.

The arrangement of the U-shaped intermediate turns on a printed circuit, with the positioning of the magnetic circuits on the printed circuit, enables the turns of the magnetic circuit to be well spaced out in order to reduce the capacitive coupling effects, in particular between the conductors of the intermediate windings (16, 17) and the magnetic circuits. Secondly, the small number of turns in the intermediate windings also brings about a reduction in the capacitive coupling, and results in good circuit isolation.

The crossing of the intermediate turns 16a and 16b and 17a and 17b respectively, cancels out the magnetic leakage fields H1, H2 (see FIG. 4) generated by the half loops of the 8-shaped winding, and as a consequence reduces the parasitic fields magnetic that can be emitted by the isolating device.

The mounting of the primary and secondary sides on separate circuit boards 18, 19 (FIG. 3a) advantageously raises the breakdown voltage of the device and eliminates the surface leakage currents, because of the resulting air space, or when filled with an insulating resin between the circuit boards.

1. An electrical power supply for electronic circuits placed in a high-voltage environment, including an insulating device interconnecting the low-voltage side (secondary side) to the high-voltage side (primary side), where the isolating device includes a primary-side magnetic circuit (13a) coupled by means of a primary winding (14) to a power supply (12) of the electronic circuit in the high-voltage environment, a secondary-side magnetic circuit (13c) coupled by means of a secondary windings (15) to a low-voltage-side current source (10), and at least one intermediate magnetic circuit (13b) between the primary and secondary magnetic circuits, coupled to the latter by means of intermediate windings, where the intermediate windings (16, 17) include parts of turns mounted on at least one circuit board (18, 19).

2. An electrical power supply according to claim 1, characterised in that the parts of turns are in the form of U-shaped rigid conductors.

3. An electrical power supply according to claim 2, characterised in that the U-shaped conductors are formed by stamping.

4. An electrical power supply according to claim 2 or 3 characterised in that the circuit board or boards include conducting tracks to interconnect the U-shaped conductors so as to close the turns in the intermediate windings.

5. An electrical power supply according to any of the preceding claims, characterised in that there are at least two circuit boards, one on the primary side and one on the secondary side, separated by a space.

6. An electrical power supply according to any of the preceding claims, characterised in that the parts of turns in the U-shaped intermediate windings of the isolating device are formed and arranged so as to be spaced from the magnetic circuit by a distance corresponding to about a quarter of the diameter of the opening formed by the magnetic circuit, or more.

7. An electrical power supply according to any of the preceding claims, characterised in that the intermediate windings (16, 17) form a closed loop essentially in the form of an “8”.

8. An electrical power supply according to any of the preceding claims, characterised in that the low-voltage-side current source (10) is a stabilised sinusoidal voltage source.

9. An electrical power supply according to any of the preceding claims, characterised in that the high-voltage side power supply (12) includes a rectifier and filter circuit, in order to generate a direct current with no alternating component.

10. An instrument for measuring electrical magnitudes on high-voltage lines, including a power supply device according to any of the preceding claims, a sensor (3) placed on the high-voltage side and a processing unit (5) placed on the low-voltage side.

11. An instrument according to claim 10, characterised in that the sensor unit includes a differential voltage sensor for measuring differential voltages between two high-voltage phases, as well as an analogue-digital converter for transmission of the measurement signals to the processing unit.

12. An instrument according to claim 11, characterised in that the sensor unit includes an oscillator (9) connected to the analogue-digital converter, sending a synchronising signal to a digital-analogue converter in the processing unit, in parallel with digital measurement signal.

13. An instrument according to claim 11 or 12, characterised in that the processing unit (5) and the sensor unit (3) communicate by means of optical fibres.
